(19) United States
(12) Patent Application Publication
(10) Pub. No.: US 2012/0087766 A1
(43) Pub. Date: Apr. 12, 2012

(54) TRANSFER MODULE

(75) Inventor: Tsutomu Hiroki, Yamanashi (JP)

(73) Assignee: TOKYO ELECTRON LIMITED, Tokyo (JP)

(21) Appl. No.: 13/375,895

(22) PCT Filed: May 20, 2010
(86) PCT No.: PCT/JP2010/058497

§ 371 Date: Dec. 15, 2011

(30) Foreign Application Priority Data
Jun. 3, 2009 (JP) 2009-134496

(51) Int. Cl. H01L 21/677

(52) U.S. Cl. 414/219

(57) ABSTRACT

There is provided a transfer module capable of enhancing strength of a transfer chamber. An openable/closable cover is provided at the transfer chamber configured to be evacuable to vacuum. A robot is provided in the transfer chamber. The robot has hollow rotation shafts at a part of a device for transferring a processing target object W. A pillar for supporting the cover in a closed state is positioned within the hollow rotation shafts of the robot. Since the pillar supports a load applied to the cover by an atmospheric pressure, a thickness of the cover can be reduced, so that manufacturing cost can be reduced. Further, the robot is not interfered by the pillar when the robot rotates the processing target object W about the rotation shafts or moves the processing target object W in a radial direction.

### TECHNICAL FIELD

The present disclosure relates to a transfer module including a transfer chamber connected to a processing chamber for processing a target object such as a semiconductor wafer, a liquid crystal substrate or an organic EL device and configured to be evacuable to vacuum level; and a robot provided in the transfer chamber and configured to transfer the target object between the processing chamber and the transfer chamber.

### BACKGROUND ART

In a manufacturing process of a semiconductor device or a FPD (Flat Panel Display), various processes such as a film formation process, an etching process, an oxidation process and a diffusion process are performed on a processing target object such as a semiconductor wafer or a liquid crystal substrate. These processes are performed in a processing chamber of a process module. In order to stably perform the processes in the process chamber, the inside of the processing chamber is maintained in vacuum. In order to replace processing target objects while maintaining the inside of the processing chamber in vacuum, a transfer chamber connected with the processing chamber is also maintained in vacuum. The transfer chamber has therein a robot for transferring the processing target objects between the processing chamber and the transfer chamber.

In a cluster type semiconductor device manufacturing apparatus, a transfer module (TM) equipped with a robot for transferring a wafer is provided at a center of the apparatus, and a multiple number of process modules (PM) for performing various processes on the wafer are radially arranged around the transfer module. The transfer module is connected with a load lock chamber configured to transfer the processing target object to/from the outside under an atmospheric pressure. The load lock chamber is formed as a small room whose inside is easily switchable between at a vacuum condition and at an atmospheric pressure condition. A robot positioned at the outside under the atmospheric pressure transfers the wafer into the load lock chamber. After the inside of the load lock chamber is turned into vacuum, the robot of the transfer module holds the wafer within the load lock chamber and loads the wafer into the transfer chamber. Then, the robot of the transfer module loads the wafer into the processing chamber of the process module. Upon the completion of the process in the transfer module, the wafer is received by the robot of the transfer module from the processing chamber, and the robot transfers the wafer back into the load lock chamber. Then, the inside of the load lock chamber is returned to the atmospheric pressure, and the robot provided at the outside under the atmospheric pressure unloads the wafer from the load lock chamber.

Meanwhile, a single process module for processing a liquid crystal substrate is connected to a single transfer module having a robot for transferring the substrate. In such a configuration, since the transfer chamber also serves as a load lock chamber, the inside of the transfer chamber is configured to be switchable between at a vacuum condition and at an atmospheric pressure condition.

The robot of the transfer module is required to have a function of rotating the processing target object on a horizontal plane in order to transfer the processing target object even in a narrows space within the transfer chamber or a function of moving the processing target object in a radial direction.

As the robot having such rotating and extending/contracting functions, there are known a frog-leg type robot (Paten Document 1) having four links like frog's legs; a SCARA type robot (Patent Document 2) in which a multiple number of linked arms are moved in a horizontal direction; and a cylindrical coordinate system robot (Patent Document 3) in which an arm is rotated on a horizontal plane and a slider provided at the arm slides in a radial direction with respect to the arm.

Patent Document 1: Japanese Patent Laid-open Publication No. H03-136779
Patent Document 2: Japanese Patent Laid-open Publication No. H08-274140

### Patent Document 3: Japanese Patent Laid-open Publication No. 2004-165579

### DISCLOSURE OF THE INVENTION

### [Problems to Be Solved by the Invention]

Recently, in order to reduce cost per a chip, a wafer size has been getting larger, e.g., about 300 mm to about 450 mm in diameter. Such increase of the wafer size has accompanied scale-up of a transfer chamber. However, even if a size of the transfer chamber is scaled up, it has been difficult to cope with the scale-up of the wafer size with a configuration of the conventional transfer chamber. The reason for this is as follows. The conventional transfer chamber is provided with an openable/closable cover for the cleaning of the inside of the transfer chamber or maintenance of the robot. Since the inside of the transfer chamber is in vacuum, a load in a ton unit is applied to the cover by an atmospheric pressure. If the area of the cover is enlarged, the load applied to the cover would also be increased in proportion to the area of the cover. Since the cover is required to be strong enough, a large-scaled countermeasure, such as increasing a thickness of the cover or additionally using a reinforcement beam, needs to be taken. Further, in order to open and close the heavy cover easily, the size of an opening/closing assist device such as a gas spring for opening/closing the cover would also be increased. Such countermeasures would cause additional cost-up of the transfer chamber.

Patent Document 1 describes a rotatable shaft is provided between an upper wall and a lower wall of the transfer chamber (pages 1 to 9 and FIG. 10 of Patent Document 1). In Patent Document 1, thrust bearings are provided at an upper end and a lower end of the shaft, and the thrust bearings guide rotation of the shaft and support the atmospheric pressure applied to the upper wall of the transfer chamber. Since one of the thrust bearings that might become a source of particles is located higher than a processing target object, the particles would adhere to the processing target object.

The present disclosure provides a transfer module capable of enhancing strength of the transfer chamber and preventing adhesion of particles to a processing target object.

The cover of the transfer chamber is periodically opened in order to clean the inside of the transfer chamber or to check the robot therein. To open the cover, the inside of the transfer chamber needs to be returned to the atmospheric pressure. For the purpose, a gas such as a nitrogen gas is supplied into the transfer chamber. When the processing target object is transferred between the transfer module and the process module, a pressure control gas is also supplied into the transfer chamber so as to prevent a processing gas within the process module from entering the transfer chamber.

When the nitrogen gas or the pressure control gas is supplied into the transfer chamber, the gas needs to be uniformly diffused in the inside of the transfer chamber even when the size of the transfer chamber is scaled up. To meet such a requirement, the present disclosure also provides a transfer module capable of uniformly diffusing a gas therein.

### [Means for Solving the Problems]

In accordance with one aspect of the present invention, there is provided a transfer module including a transfer chamber connected to a processing chamber for processing a target object and configured to be evacuable to vacuum; and a robot, provided in the transfer chamber, for transferring the target object between the processing chamber and the transfer chamber. Here, the transfer chamber may have an openable/closable cover, the robot has a hollow rotation shaft at a part of a device for transferring the target object, and a pillar for supporting the cover in a closed state is positioned within the hollow rotation shaft.

In accordance with another aspect of the present disclosure, there is provided a transfer module including a transfer chamber connected to a processing chamber for processing a target object and configured to be evacuable to vacuum; and a robot, provided in the transfer chamber, for transferring the target object between the processing chamber and the transfer chamber. Here, the transfer chamber may have an openable/closable cover, the robot has a hollow rotation shaft at a part of a device for transferring the target object, and a pillar having a gas discharge hole for discharging a gas into the transfer chamber is positioned within the hollow rotation shaft.

### [Effect of the Invention]

In accordance with one aspect of the present disclosure, since a pillar is provided within hollow rotation shafts, a robot may not be interfered by the pillar when the robot rotates a processing target object about the rotation shafts or moves the processing target object in a radial direction. Moreover, since the pillar supports the load applied to the cover by an atmospheric pressure, a thickness of a cover can be reduced, so that manufacturing cost can be reduced. Further, since the rotation shafts do not support the cover, there is no need to provide a bearing at a position above the processing target object. Thus, adhesion of particles to the processing target object can be avoided.

In accordance with another aspect of the present disclosure, by providing a pillar capable of discharging a gas into hallow rotation shafts of a robot, the gas can be discharged from a substantially center of a transfer chamber. Thus, even when a size of the transfer chamber is increased, it may be still possible to uniformly diffuse the gas within the transfer chamber.

### BRIEF DESCRIPTION OF THE DRAWINGS

FIG. 1 is a plane view of a cluster type semiconductor device manufacturing apparatus.

FIG. 2 is a perspective view of a transfer module in accordance with an embodiment of the present disclosure.

FIG. 3 is a cross sectional view of the transfer module.

FIGS. 4(a) to 4(d) are diagrams illustrating operations of a first transfer device and a second transfer device of a robot.

FIGS. 5(a) and 5(b) are a perspective view and a cross sectional view illustrating gas discharge holes of a pillar, respectively;

FIG. 6 is a cross sectional view illustrating an adhesion preventing unit.

FIG. 7 is a perspective view of a SCARA type robot;

FIG. 8 is a side view of a cylindrical coordinate system robot.

FIG. 9 is a plane view of an inline type semiconductor device manufacturing apparatus.

### BEST MODE FOR CARRYING OUT THE INVENTION

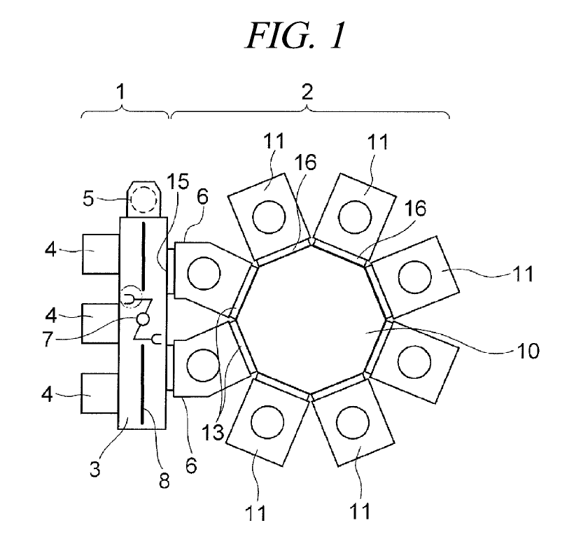

Hereinafter, illustrative embodiments of a transfer module in accordance with the present disclosure will be described with reference to the accompanying drawings. FIG. 1 illustrates an example in which a transfer module in accordance with the present disclosure is applied to a cluster type semiconductor device manufacturing apparatus. This semiconductor device manufacturing apparatus includes a transfer system 1 and a processing system 2.

The transfer system 1 includes a longitudinally elongated transfer chamber 3. The transfer chamber 3 has ports 4 at a lateral side thereof, and a cassette container accommodating therein a multiple number of wafers as processing target objects is mounted on each port 4. Further, provided at one end of the transfer chamber 3 in a lengthwise direction is a position alignment unit 5 for aligning a position of the wafer by detecting, e.g., a notch of the wafer. The transfer chamber 3 also includes a multi-joint robot 7 for transferring the wafer between the port 4 and load lock chambers 6. The multi-joint robot 7 has a slide shaft 8 so as to be slidable in the lengthwise direction of the transfer chamber 3. A pickup unit of the multi-joint robot 7 is movable both in a vertical direction and in a horizontal direction so as to transfer the wafer. The pickup unit holds the wafer.

A polygonal transfer module 10 is positioned at a center of the processing system 2. A multiple number of process modules 11 are radially arranged around the transfer module 10. The respective process modules 11 are configured to perform various processes such as a film formation process, an etching process, an oxidation process and a diffusion process on the wafer W in an evacuated processing chamber. The transfer module 10 is connected with the load lock chambers 6. Each load lock chamber 6 is formed as a small room configured to be evacuated to vacuum and returned back to an atmospheric pressure, repetitively. The transfer module 10 is connected with the process modules 11 via gate valves 16, and the transfer module 10 is connected with the load lock chambers 6 via gate valves 13. The load lock chambers 6 are connected to the transfer chamber 3 via gate valves 15.

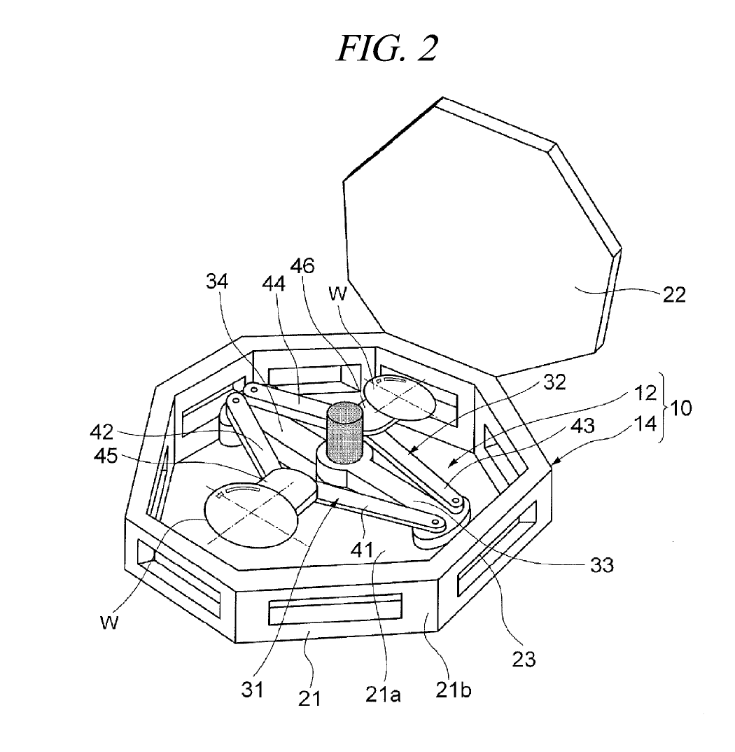

As depicted in FIG. 2, the transfer module 10 includes a transfer chamber 14 having a polygonal shape as a plane shape; and a robot 12 positioned within the transfer chamber 14. The robot 12 receives an unprocessed wafer transferred into the load lock chamber 6 and loads the unprocessed wafer into the transfer module 10. Then, the robot 12 loads the unprocessed wafer into the process module 11. The robot 12 has a function of rotating the wafer and moving the wafer in a radial direction on a horizontal plane in the transfer chamber. To elaborate, the robot 12 serves to rotate the wafer W on the horizontal plane and allow the wafer W to face the radially arranged process modules 11 or the load lock chambers 6. Then, the robot 12 carries the wafer W in a radial direction and transfers the wafer W from the transfer chamber 14 into the process module 11 or the load lock chamber 6.

An overall operation of the semiconductor device manufacturing apparatus is as follows. As illustrated in FIG. 1, the multi-joint robot 7 takes out the wafer from the cassette container on the port 4, and, while holding the wafer thereon, the multi-joint robot 7 transfers the wafer into the position alignment unit 5. After a position of the wafer is aligned by the position alignment unit 5, the multi-joint robot 7 transfers the wafer into the load lock chamber 6. At the moment, the inside of the load lock chamber 6 is maintained at an atmospheric pressure.

Thereafter, the valve 15 of the load lock chamber 6 at the side of the transfer chamber 3 is closed, and the load lock chamber 6 is evacuated to vacuum. Afterward, the gate valve 13 is opened, and the load lock chamber 6 communicates with the transfer module 10. The inside of the transfer module 10 was previously maintained in vacuum. The robot 12 positioned in the transfer module 10 holds the wafer from the load lock chamber 6 and loads the wafer into the transfer chamber 14. Then, the robot 12 transfers the wafer into one of the process modules 11. Upon the completion of the process in the process module 11, the robot 12 takes out the wafer from the process module 11 and transfers the wafer into another process module 11 (at a next site) for performing a next process. Upon the completion of all necessary processes in the process modules 11, the robot 12 transfers the wafer W from the process module 11 that performs a final process into the load lock chamber 6.

Then, the gate valve 13 of the load lock chamber 6 is closed, and the gate valve 15 is opened. The inside of the load lock chamber 6 is returned back to the atmospheric pressure. Then, the multi-joint robot 7 unloads the processed wafer out of the load lock chamber 6.

As shown in FIG. 2, the transfer chamber of the transfer module 10 may have a polygonal box shape corresponding to the number or the layout of the process modules. By way of non-limiting example, the transfer chamber may have a tetragonal box shape, a hexagonal box shape or an octagonal box shape. The length of each one side of the process module 11 may range from about 800 mm to about 900 mm. If a single process module 11 is connected to the one side of the polygonal transfer chamber 14, the length of the one side of the polygonal transfer chamber 14 may be set to be, e.g., about 1000 mm. If two process modules 11 are connected to the one side of the polygonal transfer chamber 14, the length of the one side of the polygonal transfer chamber 14 may be set to be, e.g., about 1800 mm.

The transfer chamber 14 includes a main body 21 accommodating therein the robot 12; and a cover 22 capable of opening and closing the main body 21. The main body 21 includes a polygonal bottom wall 21a and a sidewall 21b surrounding the bottom wall 21a. Slits 23 are formed in the sidewall 21b, and the wafer is loaded and unloaded through the slit 23. Further, the cover 22 is provided to the sidewall 21b to be opened and closed, and an opening/closing operation of the cover 22 is performed by a hinge provided at the sidewall 21b. Further, a non-illustrated O-ring is provided between the cover 22 and the sidewall so as to seal up the inside of the transfer chamber 14. The main body 21 and the cover 22 may be made of aluminum or stainless steel and may be coated with a protection film such as alumina.

The cover 22 has a polygonal shape corresponding to the shape of the polygonal main body 21. The cover 22 has a sensor for measuring the wafer within the transfer chamber 14 or a window for allowing an operator to observe the wafer within the transfer chamber 14 with naked eyes. While the wafer is being processed, the cover 22 of the transfer chamber 14 is kept closed, and the inside of the transfer chamber 14 is maintained in vacuum. The cover 22 is opened to clean the inside of the transfer chamber 14 or to check the robot 12.

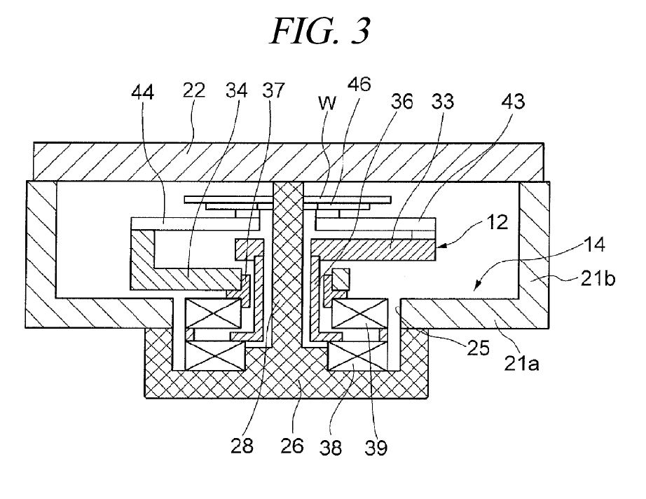

As shown in a cross sectional view of FIG. 3, an opening 25 is formed at a center of the bottom wall 21a, and a structure 26 for closing the opening 25 is provided under the bottom wall 21a. This structure 26 serves as a base of the robot 12. A pillar 28 is formed on the center of the structure 26. The pillar 28 is upwardly protruded from a bottom of the structure 26 and is formed as a single body with the structure 26. Around the pillar 28, transfer devices of the robot 12 are provided.

As shown in FIG. 2, a first transfer device 31 and a second transfer device 32, each having a frog-leg structure, are positioned symmetrically with respect to the pillar 28. The robot 12 rotates the first and second transfer devices 31 and 32 and also extends and contracts the first and second transfer devices 31 and 32 in radial directions on a horizontal plane. By providing the two transfer devices 31 and 32, an idle time of the process module 11 can be reduced. To elaborate, immediately after the first transfer device 31 takes out a processed wafer W from the process module 11, the robot 12 rotates the first and second transfer devices 31 and 32 by 180° on the horizontal plane while maintaining the first and second transfer devices 31 and 32 contracted. Then, the robot 12 extends the second transfer device 32 and loads an unprocessed wafer W into the process module 11.

Each of the first and second transfer devices 31 and 32 is configured to load and unload the wafer by extending and contracting four links like frog's legs. The first and second transfer devices 31 and 32 have a first arm 33 extended from the pillar 28 in a radial direction; and a second arm 34 positioned below the first arm 33 and extended from the pillar 28 in a direction opposite to the direction of the first arm 33. The first arm 33 and the second arm 34 have same lengths.

As shown in FIG. 2, the first arm 33 is connected with a first hollow rotation shaft 36 positioned to surround the pillar 28. The second arm 34 is connected with a second hollow rotation shaft 37 positioned to surround the first rotation shaft 36. The first rotation shaft 36 and the second rotation shaft 37 are rotated by a first hollow direct drive motor 38 and a second hollow direct drive motor 39 connected to the structure 26, respectively. Stators of the direct drive motors 38 and 39 are connected to the structure 26, while their rotors are connected to the rotation shafts 36 and 37, respectively. A rotation center of each of the first and second rotation shafts 36 and 37 coincides with a center of the pillar 28. Here, instead of using the direct drive motors 38 and 39, the first and second rotation shafts 36 and 37 may be rotated by using hollow planet gears.

As illustrated in FIG. 2, the first transfer device 31 also has a first link 41 rotatably connected to a leading end of the first arm 33 by a pin; and a second link 42 connected to a leading end of the second arm 34 by a pin. The lengths of the first and second links 41 and 42 are same and longer than the lengths of the first and second arms 33 and 34. A first supporting plate 45 as a supporting body for supporting the wafer W is rotatably connected to leading ends of the first and second links 41 and 42 by a pin. The first and second links 41 and 42 are rotated on a horizontal plane.

The second transfer device 32 also has a third link 43 rotatably connected to the leading end of the first arm 33 by a pin; and a fourth link 44 rotatably connected to the leading end of the second arm 34 by a pin. A second supporting plate 46 for supporting the wafer W is rotatably connected to leading ends of the third and the fourth links 43 and 44 by a pin. The third and the fourth links 43 and 44 are rotated on a horizontal plane.

The first and second transfer devices 31 and 32 are moved up and down by a non-illustrated elevation device while holding the wafers W on the supporting plates 45 and 46 thereof.

As illustrated in FIG. 3, the pillar 28 is protruded upward through the first and second rotation shafts 36 and 37. A top end of the pillar 28 comes into contact with the cover 22 in a closed state. When the inside of the transfer chamber 14 is in vacuum, a load in a ton unit is applied to the cover 22 by an atmospheric pressure. The load applied to the cover 22 is supported by the pillar 28 and the sidewall 21b. Only a compressive load is applied to the pillar 28 from the cover 22, but no moment is applied thereto. The diameter of the pillar 28 is set such that the compressive load applied to the pillar 28 becomes equal to or smaller than a buckling load of the pillar 28. By way of non-limiting example, the diameter of the pillar 28 may be set to be about 50 mm to about 60 mm.

A sensor for measuring the wafer is provided at the cover 22. In order to prevent a position deviation of the sensor, it is necessary to suppress deformation of the cover 22 by increasing strength of the cover 22. When the cover 22 is supported only by the sidewall 21b, since a supporting span of the cover 22 by the sidewall 21b is large, a thickness of the cover 22 needs to be large. In contrast, as in the present embodiment, by supporting the cover 22 with the pillar 28 at the center of the transfer chamber 14, the thickness of the cover 22 can be reduced much smaller than that of the conventional cover, so that cost can be cut greatly. Further, since the weight of the cover 22 is reduced, the opening/closing assist device can also be simply and easily made (omitted when necessary). Thus, cost cut may be enabled as well.

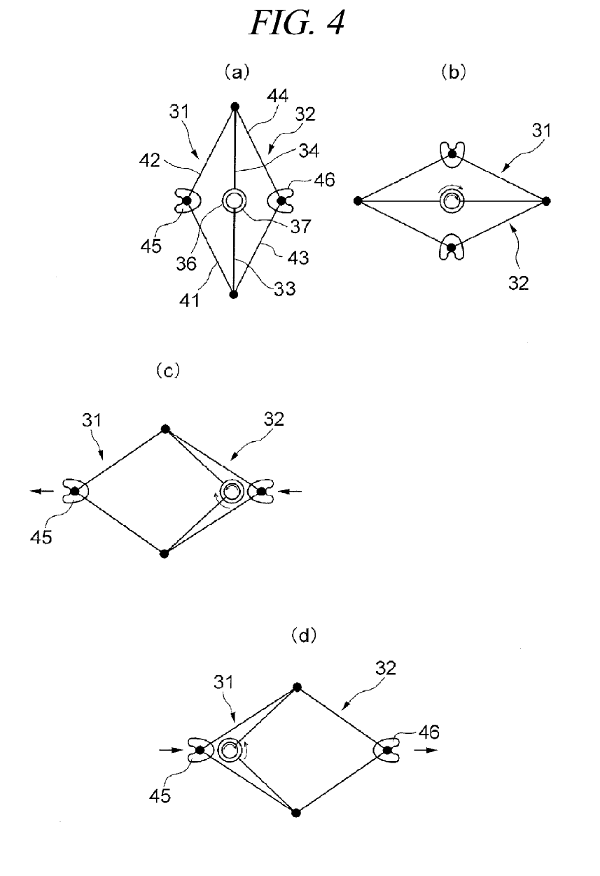

FIGS. 4(a) to 4(d) are diagrams illustrating operations of the first and second transfer devices 31 and 32. As shown in FIG. 4(a), if positions of the first and second arms 33 and 34 are aligned on the same line with each other (i.e., if an angle formed by the first and second arms 33 and 34 becomes about 180°), the first and second transfer devices 31 and 32 are contracted. In this state, if the first and second rotation shafts 36 and 37 are rotated in the same direction, the first and second transfer devices 31 and 32 in the contracted state can be rotated on a horizontal plane (see FIG. 4(b)). In this way, by rotating the first and second transfer devices 31 and 32 in the contracted state, a radius of rotation can be reduced.

By way of example, with the first and second transfer devices 31 and 32 contracted (FIG. 4(a)), if the first rotation shaft 36 is rotated counterclockwise while the second rotation shaft 37 is rotated clockwise, the first transfer device 31 is extended, so that the first supporting plate 45 can be moved in a radial direction (see FIG. 4(c)). At this time, the second transfer device 32 approaches the pillar 28 to the extent that it does not come into contact with the pillar 28. Meanwhile, with the first and second transfer devices 31 and 32 contracted (FIG. 4(a)), if the first rotation shaft 36 is rotated clockwise while the second rotation shaft 37 is rotated counterclockwise, the second transfer device 32 is extended, so that the second supporting plate 46 can be moved in a radial direction (FIG. 4(d)). At this time, the first transfer device 31 is moved close toward the pillar 28 to the extent that it does not come into contact with the pillar 28.

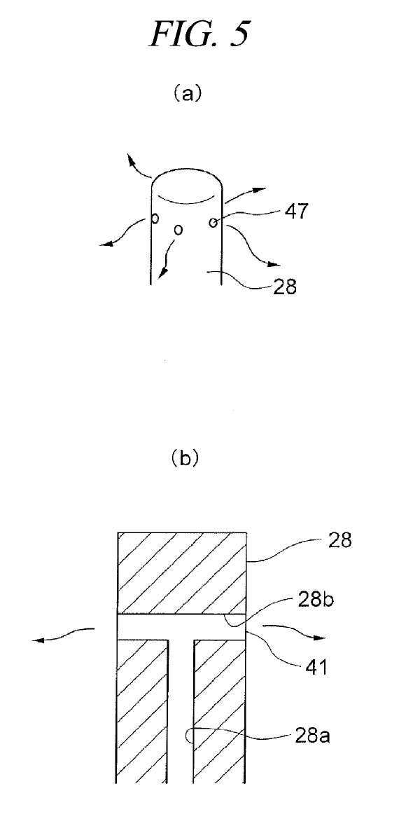

FIG. 5(a) illustrates a configuration example of the pillar 28 provided with gas discharge holes 47. As depicted in FIG. 5(b), a vertically elongated gas passage 28a is formed in a central portion of the pillar 28. The gas passage 28a is radially branched at an upper end portion of the pillar 28 (see 28b). The gas discharge holes 47 are formed on an outside surface of the pillar 28 along a circumference thereof at a regular interval. By discharging a gas such as a nitrogen gas from the gas discharge holes 47, the inside of the transfer chamber 14 can be returned back to the atmospheric pressure.

Moreover, when the wafer is transferred between the transfer module 10 and the process modules 11, in order to suppress a processing gas in the process modules 11 from entering the transfer chamber 14, it may be possible to discharge a pressure control gas from the gas discharge holes 47. Since the pillar 28 is positioned substantially at the center of the transfer chamber 14, the pressure control gas can be discharged toward the process modules 11 radially arranged around the transfer chamber 14 with a substantially same distance. Accordingly, leakage of the processing gas from all the process modules 11 can be prevented. If the pillar 28 is deviated from the center of the transfer chamber 14, however, it would become difficult to prevent leakage of the processing gas from a farthest process module 11 from the pillar 28.

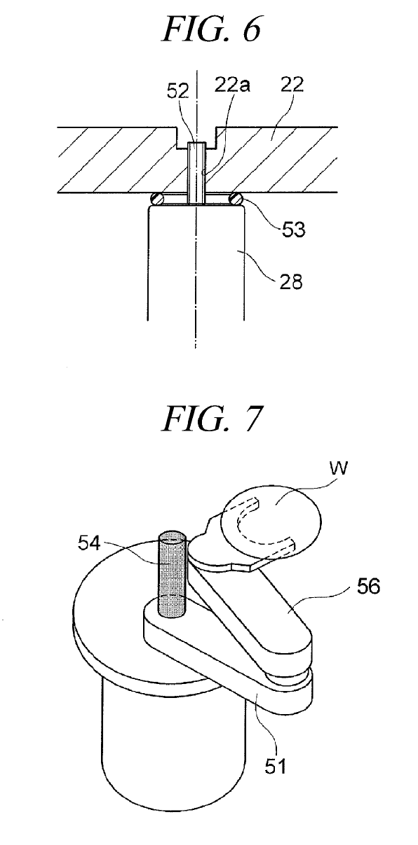

FIG. 6 illustrates a configuration example in which an adhesion preventing unit is provided on top of the pillar 28. A female screw 22a is formed in a center of the cover 22, and a male screw 52 is screwed into the female screw 22a. A bottom end of the male screw 52 is in contact with the top end of the pillar 28. By turning the male screw 52, the cover 22 can be lifted up from the pillar 28. An annular O-ring 53 is positioned to surround the male screw 52 between a top surface of the pillar 28 and a bottom surface of the cover 22. The load of the cover 22 is supported by the pillar 28 via the O-ring 53.

As mentioned above, the O-ring having a large diameter is positioned between the sidewall 21b and the cover 22 so as to seal up the inside of the transfer chamber 14. This large-diameter O-ring is made of fluorine-based rubber. The fluorine-based rubber has adhesiveness. Accordingly, if time elapses after the cover 22 is pressed by the atmospheric pressure, the large-diameter O-ring adheres to the cover 22. In such a state, it may become difficult to open the cover 22 even if the inside of the transfer chamber 14 is returned to the atmospheric pressure. In accordance with the present disclosure, by providing the adhesion preventing unit, the cover 22 can be lifted up from the pillar 28. Even when the O-ring adheres to the pillar 28, the cover 22 can be still lifted away.

The application of the present disclosure may not be limited to the aforementioned robot having the frog-leg type transfer devices. By way of example, the present disclosure may be also applicable to a SCARA type robot or a cylindrical coordinate system robot as long as the robot has a device capable of rotating the wafer about a hollow rotation shaft and moving the wafer in a radial direction.

FIG. 7 illustrates a SCARA type robot. The SCARA type robot has a multiple number of arms 51 and 56 rotated on a horizontal plane. The first arm 51 is rotated about a non-illustrated hollow rotation shaft. A pillar 54 is positioned within the hollow rotation shaft. In this SCARA type robot, the wafer W can be rotated on a horizontal plane by rotating the first arm 51. Further, by rotating the first arm 51 and the second arm 56 in opposite directions, the wafer W can be moved in a radial direction.

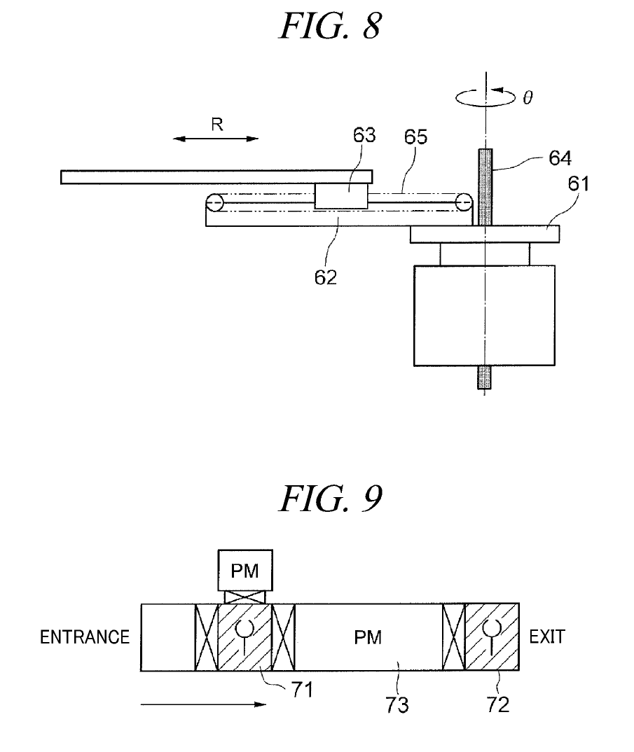

FIG. 8 illustrates a cylindrical coordinate system robot. This robot has a θ shaft 61 for rotating the wafer and an R shaft 62 for sliding the wafer in a radial direction. The θ shaft 61 has a hollow rotation shaft. A pillar 64 is inserted through the hollow rotation shaft of the θ shaft 61. A linear guide for guiding the movement of the wafer in the radial direction is provided at the R shaft 62. By straightly driving a block 63 of the linear guide provided at the R shaft 62 by a belt 65 or the like, the wafer W can be moved in the radial direction.

The present disclosure may not be limited to the aforementioned embodiment but can be modified in various ways without departing from the spirit of the present disclosure.

By way of example, the transfer module in accordance with the present disclosure may be applied to, e.g., a FPD manufacturing apparatus without being limited to the semiconductor device manufacturing apparatus. In such a case, a single process module for performing a process may be connected to a single transfer module equipped with a robot for transferring a liquid crystal substrate. Further, a transfer chamber may serve as a load lock chamber, and the inside of the load lock chamber may be switched between a vacuum condition and an atmospheric pressure condition.

Moreover, as shown in FIG. 9, the present disclosure may also be applicable to an inline type semiconductor device manufacturing apparatus having separate entrance and exit for a wafer. A transfer module 71 at the entrance side may only serve to load the wafer W into a process module 73, while a transfer module 72 at the exit side may only serve to unload the wafer from the process module 73.

The robot of the transfer module may not have two transfer devices but only have a single transfer device. If the inside of the processing chamber is cleaned after the wafer is processed in the process module, the processes can be performed well even if the robot has only the single transfer device.

In case that the gas discharge holes are formed at the pillar, the pillar may not support the cover. Further, by way of example, a CCD camera for monitoring a movement of the wafer within the transfer chamber may be provided at the pillar.

This application claims priority to Japanese Patent Application No. 2009-134496, field on Jun. 3, 2009, which is incorporated herein by reference in its entirety.

### EXPLANATION OF CODES

10: Transfer module
11: Process module
12: Robot
14: Transfer chamber
21: Main body
22: Cover
26: Structure
28, 54, 64: Pillar
31: First transfer device
32: Second transfer device
33: First arm
34: Second arm
36: First rotation shaft
37: Second rotation shaft
41: First link
42: Second link
43: Third link
44: Fourth link
45: First supporting plate (supporting body)
46: Second supporting plate (supporting body)
47: Gas discharge hole
52: Male screw (screw)
53: O-ring (sealing member)

1. A transfer module comprising:
a transfer chamber connected to a processing chamber for processing a target object and configured to be evacuable to vacuum; and
a robot, provided in the transfer chamber, for transferring the target object between the processing chamber and the transfer chamber,
wherein the transfer chamber has an openable/closable cover,
the robot has a hollow rotation shaft at a part of a device for transferring the target object, and
a pillar for supporting the cover in a closed state is positioned within the hollow rotation shaft.

2. The transfer module of claim 1, wherein the pillar is provided with a gas discharge hole for discharging a gas into the transfer chamber.

3. A transfer module comprising:
a transfer chamber connected to a processing chamber for processing a target object and configured to be evacuable to vacuum; and
a robot, provided in the transfer chamber, for transferring the target object between the processing chamber and the transfer chamber,
wherein the transfer chamber has an openable/closable cover,
the robot has a hollow rotation shaft at a part of a device for transferring the target object, and
a pillar having a gas discharge hole for discharging a gas into the transfer chamber is positioned within the hollow rotation shaft.

4. The transfer module of claim 1,
wherein a screw capable of being brought into contact with a top portion of the pillar is screwed to the cover, and
the cover is lifted up from the pillar by turning the screw in contact with the pillar.

5. The transfer module of claim 4, wherein an annular sealing member is provided between the top portion of the pillar and the cover so as to surround the screw.

6. The transfer module of claim 1,
wherein the device of the robot is an extensible/contractible frog-leg type transfer device, and
the frog-leg type transfer device includes:
a first hollow rotation shaft;
a second hollow rotation shaft positioned at an inside or an outside of the first hollow rotation shaft;
a first arm connected to the first hollow rotation shaft;
a second arm connected to the second hollow rotation shaft;
a first link rotatably connected to the first arm;
a second link rotatably connected to the second arm; and
a first supporting member, rotatably connected to the first and second links, for supporting the target object,
wherein the pillar is inserted into the first and second hollow rotation shafts.

7. The transfer module of claim 6,
wherein the frog-leg type transfer device includes a first frog-leg type transfer device and a second frog-leg type transfer device symmetrically arranged with respect to the pillar,
the first frog-leg type transfer device has the first and second hollow rogation shafts, the first and second arms, the first and second links, and the first supporting member,
the second frog-leg type transfer device has the first and second hollow rotation shafts, the first and second arms, a third link rotatably connected to the first arm, a fourth link rotatably connected to the second arm, and a second supporting member, rotatably connected to the third and the fourth links, for supporting a target object, and
when one of the first and second frog-leg type transfer devices in a contracted state is extended, the other of the first and second frog-leg type transfer devices is moved close to the pillar without coming into contact with the pillar.
